(19) United States
(12) Patent Application Publication
(10) Pub. No.: US 2025/0040189 A1
(43) Pub. Date: Jan. 30, 2025

(54) DISPLAY DEVICE AND MANUFACTURING METHOD THEREOF

(71) Applicant: Samsung Display Co., Ltd., Yongin-Si (KR)

(72) Inventors: Sang Jin PARK, Yongin-si (KR); DAEGEON KIM, Yongin-si (KR); JIMIN PARK, Yongin-si (KR); JINSEOK SEO, Yongin-si (KR); YONGHAN LEE, Yongin-si (KR); YOOGANG JEON, Yongin-si (KR)

(21) Appl. No.: 18/411,104

(22) Filed: Jan. 12, 2024

(30) Foreign Application Priority Data
Jul. 24, 2023 (KR) 10-2023-0096132

(51) Int. Cl. H01L 29/786; H01L 25/075; H01L 25/16; H01L 29/66

(52) U.S. Cl. CPC H01L 29/7869; H01L 25/0753; H01L 25/167; H01L 29/6675; H01L 29/78696

(57) ABSTRACT

A display device according to an embodiment includes a substrate and a transistor including an oxide semiconductor layer and a gate electrode disposed on the oxide semiconductor layer. The oxide semiconductor layer includes a channel region and a first source region disposed adjacent to the channel region and a second source region disposed adjacent to the first source region, and the drain region include a first drain region disposed adjacent to the channel region and a second drain region disposed adjacent to the first drain region. Each of the first source region and the first drain region includes a first impurity ion, and each of the second source region and the second drain region includes a second impurity ion which are different from the first impurity.

### CROSS-REFERENCE TO RELATED APPLICATION

This application claims priority to and the benefit of Korean Patent Application No. 10-2023-0096132 filed in the Korean Intellectual Property Office on Jul. 24, 2023, the entire contents of which are incorporated herein by reference.

### BACKGROUND

### (a) Field

The present disclosure relates to a display device and a manufacturing method of the display device.

### (b) Description of the Related Art

A display device is a device that displays a screen, and includes a liquid crystal display (LCD), an organic light emitting diode (OLED), and the like.

Such display devices are used in various electronic devices such as mobile phones, navigation devices, digital cameras, electronic books, portable game consoles, and various terminals.

The display device may include a plurality of pixels arranged in a row direction and a column direction.

Various elements such as transistors and capacitors, and various wires capable of supplying signals to these elements may be located in each pixel.

Various elements such as transistors and capacitors are controlled by signals applied at various times to display images, and light emitting display devices are controlled to emit light of a specific luminance to display images.

### SUMMARY

Embodiments are intended to provide a semiconductor layer including at least two regions with different carrier concentrations. Embodiments are intended to provide a stable threshold voltage value through the semiconductor layer.

Embodiments are intended to increase the resolution of a display device by providing an oxide semiconductor layer having a short channel length.

A display device according to an embodiment may include a substrate and a transistor, the transistor including an oxide semiconductor layer as an active layer and a gate electrode disposed on the oxide semiconductor layer to overlap the oxide semiconductor layer. The second oxide semiconductor layer may include a channel region and a source region disposed on a first side of the channel region and a drain region disposed on s second side of the channel region. The source region may include a first source region disposed adjacent to the channel region and a second source region disposed adjacent to the first source region, and the drain region include a first drain region disposed adjacent to the channel region and a second drain region disposed adjacent to the first drain region. Each of the first source region and the first drain region may include a first impurity ion, and each of the second source region and the second drain region includes a second impurity ion which are different from the first impurity.

The second source region and the second drain region may further include the first impurity ion.

Atomic mass of the second impurity ion may be greater than the atomic mass of the first impurity ion.

The first impurity ion may be a p-type impurity and the second impurity ion may be an n-type impurity.

The first impurity ion may include B and the second impurity ion may include at least one of As, Sb, Si, Ge, and an In.

Doping concentration of the first source region and the first drain region is lower than that of the second source region and the second drain region.

A doping amount concentration of the first impurity ions may be 1×10¹² ions/cm² to 1×10¹³ ions/cm².

A doping concentration of the second impurity ions may be 1×10¹² ions/cm² to 1×10¹⁴ ions/cm².

Each of the first source region and the second source region may include B.

Each of the second source region and the second drain region may include B and at least one of As, Sb, Si, Ge, and In.

A method of manufacturing a display device according to one embodiment may include the steps of forming an oxide semiconductor layer on a substrate, forming a gate insulating layer on the oxide semiconductor layer, forming a gate electrode of an oxide transistor on the gate insulating layer, doping a first impurity ion in the oxide semiconductor layer, doping a second impurity ion in the oxide semiconductor layer. The first impurity ion includes a p-type impurity ion, and the second impurity ion includes an impurity ion of a different type from the first impurity ion. The second impurity ion may include an n-type impurity ion.

The method of manufacturing the display device may further include forming a mask which covers side surface of the gate electrode before the doping of the second impurity ion in the oxide semiconductor layer. The mask may be a photosensitive pattern.

The method of manufacturing the display device may further include removing the mask after the doping of the second impurity ion in the oxide semiconductor layer.

The first impurity ion may be B and the second impurity ion may be at least one of As, Sb, Si, Ge, and an In.

The method of manufacturing the display device may further include forming a mask which covers side surface of the gate electrode before the doping of the first impurity ion in the oxide semiconductor layer and the doping of the second impurity ion in the oxide semiconductor. The method of manufacturing the display device may further include removing the mask before the doping of the first impurity ion in the oxide semiconductor layer.

A doping amount of the first impure ion may be 1×10¹² ions/cm² to 1×10¹³ ions/cm².

A doping amount of the second impure ion may be 1×10¹² ions/cm² to 1×10¹⁴ ions/cm².

According to embodiments, the oxide semiconductor layer including at least two regions having different carrier concentrations may be provided.

A stable threshold voltage value may be provided through the semiconductor layer.

Resolution of a display device may increase by providing the oxide semiconductor layer having a short channel length.

### BRIEF DESCRIPTION OF THE DRAWINGS

FIG. 1 is a schematic perspective view illustrating a display device according to an embodiment when a user is operating the display device.

FIG. 2 is an perspective view of a display device according to an embodiment.

FIG. 3 is a circuit diagram of one pixel included in a light emitting display device according to an embodiment.

FIG. 4 is a drawing illustrating a cross-sectional structure of a light emitting display device according to an embodiment.

FIG. 5 is a drawing illustrating a second semiconductor layer according to an embodiment.

FIGS. 6, 7, 8 and 9 are cross-sectional views of a manufacturing process of a second semiconductor layer according to an embodiment.

FIGS. 10, 11, 12 and 13 are cross-sectional views of a manufacturing process of a second semiconductor layer according to another embodiment.

FIG. 14 is a graph showing threshold voltage values of transistors including an oxide semiconductor according to Examples and Comparative Examples.

### DETAILED DESCRIPTION OF THE EMBODIMENTS

Hereinafter, various embodiments of the present inventive concept will be described in detail with reference to the accompanying drawings so that those skilled in the art can easily carry out the present inventive concept.

This inventive concept may be embodied in many different forms, and is not limited to the embodiments set forth herein.

In order to clearly describe the present inventive concept, parts irrelevant to the description are omitted, and the same reference numerals are assigned to the same or similar components throughout the specification.

In addition, since the size and thickness of each component shown in the drawings are arbitrarily shown for convenience of explanation, the present inventive concept is not necessarily limited to that which is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, or plate is said to be “above” or “on” another part, this includes not only the case where it is “directly on” the other part, but also the case where another part is in the middle.

Conversely, when a part is said to be “directly on” another part, it means that there is no other part in between.

In addition, being “above” or “on” a reference part means being located above or below the reference part, and does not necessarily mean being located “above” or “on” it in the opposite direction of gravity.

In addition, throughout the specification, when a certain component is said to “include,” it means that it may further include other components without excluding other components unless otherwise stated.

Also, throughout the specification, when reference is made to a “planar image,” it means when the target part is viewed from above, and when reference is made to a “cross-sectional image,” it means when the cross section of the target part cut vertically is viewed from the side.

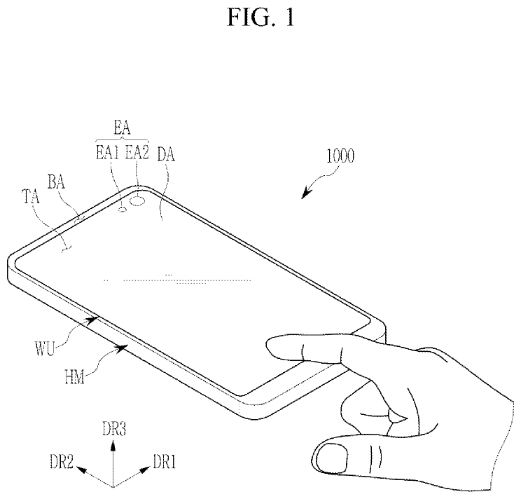

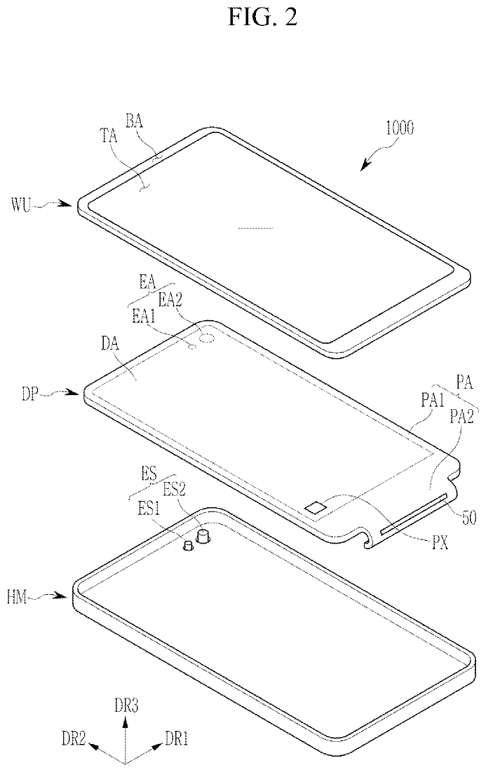

Hereinafter, a schematic structure of the display device will be described with reference to FIG. 1 and FIG. 2.

FIG. 1 is a schematic perspective view illustrating the display device according to an embodiment when a user is operating the display device, and FIG. 2 is an exploded perspective view of the display device according to an embodiment.

Referring to FIG. 1, the display device 1000 according to an embodiment is a device that displays videos or still images, and can be used as a display screen for various products such as mobile phones, smartphones, tablet PCs, mobile communication terminals, electronic notebooks, e-books, portable multimedia players (PMP), navigation, ultra mobile PCs (UMPC), as well as televisions, laptops, monitors, billboards, Internet of Things (IoT).

Also, the display device 1000 according to an embodiment can be used in wearable devices such as a smart watch, watch phone, glasses-type display, and head-mounted display (HMD).

In addition, the display device 1000 according to an embodiment includes a center information display (CID) disposed on an instrument panel of a vehicle, a center fascia or a dashboard of the vehicle, and a room mirror display instead of a side mirror of the vehicle (room mirror display), or entertainment for the back seat of a car, and can be used as a display placed on the back of the front seat.

FIG. 1 shows the display device 1000 when used as a smart phone for convenience of explanation.

The display device 1000 may display an image in a third direction DR3 on a display surface parallel to each of the first and second directions DR1 and DR2.

The display surface on which the image is displayed may correspond to the front surface of the display device 1000 and may correspond to the front surface of a cover window WU.

The image may include a still image as well as a dynamic image.

In this embodiment, the front (or upper surface) and rear surface (or lower surface) of each member are defined based on the direction in which the image is displayed.

The front surface and the rear surface oppose each other in the third direction DR3, and a normal direction of each of the front surface and the rear surface may be parallel to the third direction DR3.

The distance between the front and rear surfaces in the third direction DR3 may correspond to the thickness of the display panel in the third direction DR3.

The display device 1000 according to an embodiment may detect a user's input (refer to a hand in FIG. 1) applied from the outside.

The user's input may include various types of external inputs such as a part of the user's body, light, heat, or pressure.

In one embodiment, the user's input is shown as the user's hand being applied in the foreground.

However, the present inventive concept is not limited thereto.

User input may be provided in various forms.

Also, the display device 1000 may detect the user's input applied to the side or rear surface of the display device 1000 according to the structure of the display device 1000.

Referring to FIG. 1 and FIG. 2, the display device 1000 may include the cover window WU, a housing HM, a display panel DP, and an optical element ES.

In one embodiment, the cover window WU and the housing HM may be combined to form the exterior of the display device 1000.

The cover window WU may include an insulating panel.

For example, the cover window WU may be made of glass, plastic, or a combination thereof.

The front surface of the cover window WU may define the front surface of the display device 1000.

A transmission area TA may be an optically transparent area.

For example, the transmission area TA may have a visible light transmittance of about 90% or more.

A blocking area BA may define the shape of the transmission area TA.

The blocking area BA may be disposed adjacent to the transmission area TA and may surround the transmission area TA.

The blocking area BA may have relatively low light transmittance compared to the transmission area TA.

The blocking area BA may include an opaque material that blocks light.

The blocking area BA may have a predetermined color.

The blocking area BA may be defined by a bezel layer provided separately from the transparent substrate defining the transmission area TA, or may be defined by an ink layer inserted into or colored in the transparent substrate.

The display panel DP may include a front surface including a display area DA and a non-display area PA.

The display area DA may be an area where pixels operate according to electrical signals to emit light.

A non-display area PA of the display panel DP may include the driving unit 50.

In an embodiment, the display area DA may be an area including pixels and displaying an image, and may also be an area where a touch sensor is positioned above the pixel in the third direction DR3 to detect an external input.

The transmission area TA of the cover window WU may at least partially overlap the display area DA of the display panel DP.

For example, the transmission area TA may overlap the entire surface of the display area DA or may overlap at least a portion of the display area DA.

Accordingly, the user may view the image through the transmission area TA or provide an external input based on the image.

However, the present inventive concept is not limited thereto.

For example, within the display area DA, an area where an image is displayed and an area where an external input is sensed may be separated from each other.

The non-display area PA of the display panel DP may at least partially overlap the blocking area BA of the cover window WU.

The non-display area PA may be an area covered by the blocking area BA.

The non-display area PA is disposed adjacent to the display area DA, and may surround the display area DA.

An image is not displayed in the non-display area PA, and a driving circuit or a driving wire for driving the display area DA may be disposed in the non-display area PA.

The non-display area PA may include a first peripheral area PA1 located outside the display area DA and a second peripheral area PA2 including the driving unit 50, connection wires, and a bending area.

In the embodiment of FIG. 2, the first peripheral area PA1 is located on the third side of the display area DA, and the second peripheral area PA2 is located on the other side of the display area DA.

In one embodiment, the display panel DP may be assembled in a flat state with the display area DA and the non-display area PA facing the cover window WU.

However, the present inventive concept is not limited thereto.

A part of the non-display area PA of the display panel DP may be bent.

In this case, a part of the non-display area PA faces the rear surface of the display device 1000, so that the blocking area BA visible on the front surface of the display device 1000 can be reduced. In FIG. 2, a second peripheral area (PA2) may be bent and positioned on the rear surface of the display area DA.

Also, the display panel DP may include a component area EA which includes a first component area EA1 and a second component area EA2.

The first component area EA1 and the second component area EA2 may be at least partially surrounded by the display area DA.

The first component area EA1 and the second component area EA2 are illustrated as being spaced apart from each other, but the configuration of the first component area EA1 and the second component area EA2 are not limited thereto and may be connected at least in part.

The first component area EA1 and the second component area EA2 may be areas in which components using infrared light, visible light, or sound are disposed below the first component area EA1 and the second component area EA2.

In the display area DA, a plurality of light emitting diodes and a plurality of pixel circuit units generating and transmitting a light emitting current are formed in each of the plurality of light emitting diodes.

Here, one light emitting diode and one pixel circuit part are referred to as a pixel PX.

In the display area DA, one pixel circuit unit and one light emitting diode are formed in a one-to-one arrangement.

The first component area EA1 may include a transmission part through which light or/and sound may pass and a display part including a plurality of pixels.

The transmission part is positioned between adjacent pixels and is composed of a layer through which light or/and sound can pass.

The transmission part may be positioned between adjacent pixels, and depending on embodiments, a layer that does not transmit light, such as a light blocking member, may overlap the first component area EA1.

The number of pixels per unit area (hereinafter referred to as resolution) of the pixels (hereinafter referred to as normal pixels) included in the display area DA and the pixels included in the first component area EA1 (hereinafter referred to as first component pixels) may be the same.

The second component area EA2 includes an area made of a transparent layer to allow light to pass therethrough (hereinafter, referred to as a light transmitting area). A layer, e.g., a pixel defining layer and/or a light blocking member, may include an opening in an area corresponding to a position corresponding to the second component area EA2 so as not to block light.

The number of pixels per unit area of the pixels (hereinafter referred to as second component pixels) included in the second component area EA2 may be smaller than the number of pixels per unit area of normal pixels included in the display area DA.

As a result, the resolution of the second component pixel may be lower than that of the normal pixel.

A driving unit 50 may be mounted on the second peripheral area PA2 and may be mounted on the bending unit or located on one or both sides of the bending unit.

The driving unit 50 may be provided in the form of a chip.

The driver 50 may be electrically connected to the display area DA to transmit an electrical signal to the display area DA.

For example, the driver 50 may provide data signals to the pixels PX disposed in the display area DA.

Alternatively, the driver 50 may include a touch driving circuit and may be electrically connected to a touch sensor disposed in the display area DA.

Meanwhile, the driver 50 may include various circuits in addition to the above circuits or may be designed to provide various electrical signals to the display area DA.

Meanwhile, the display device 1000 can have a pad part located at the end of the second peripheral area (PA2), and the display device 1000 can be electrically connected to a flexible printed circuit board (FPCB) that includes a drive chip through the pad part.

Here, the driving chip positioned on the flexible printed circuit board may include various driving circuits for driving the display device 1000 or connectors for supplying power.

According to embodiments, a rigid printed circuit board (PCB) may be used instead of a flexible printed circuit board.

An optical element ES may be disposed below the display panel DP.

The optical element ES may include a first optical element ES1 overlapping the first component area EA1 and a second optical element ES2 overlapping the second component area EA2.

The first optical element ES1 may be an electronic element using light or sound.

For example, the first optical element ES1 may be a sensor that receives and uses light such as an infrared sensor, a sensor that outputs and senses light or sound to measure a distance or recognizes a fingerprint, or a small lamp that outputs light. It may be a speaker or the like that outputs sound.

In the case of an electronic element using light, light of various wavelength bands such as visible light, infrared light, and ultraviolet light can be used.

The second optical element (ES2) can be at least one of a camera, an infrared camera (IR camera), a dot projector, an infrared illuminator (IR illuminator), and a time-of-flight sensor (ToF sensor).

The housing HM may be coupled to the cover window WU.

The cover window WU may be disposed on the front surface of the housing HM.

The housing HM may be coupled to the cover window WU to provide a predetermined accommodation space.

The display panel DP and the optical element ES may be accommodated in a predetermined accommodating space provided between the housing HM and the cover window WU.

The housing HM may include a material with relatively high rigidity.

For example, the housing HM may include a plurality of frames and/or plates made of glass, plastic, or metal, or a combination thereof.

The housing HM can stably protect components of the display device 1000 accommodated in the internal space from external impact.

Hereinafter, one pixel PX located in the display area DA will be described.

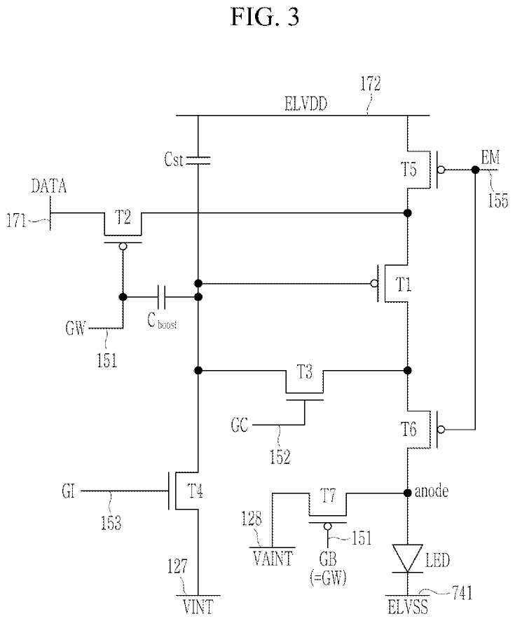

FIG. 3 is a circuit diagram of one pixel included in a light emitting display device according to an embodiment.

One pixel according to an embodiment includes a plurality of transistors T1, T2, T3, T4, T5, T6, and T7 connected to various wires 127, 128, 151, 152, 153, 155, 171, 172, and 741, a holding capacitor (Cst), a boost capacitor (C_{boost}), and a light emitting diode (LED).

Here, transistors and capacitors other than the light emitting diode (LED) constitute a pixel circuit unit.

Depending on embodiments, the boost capacitor C_{boost} may be omitted.

Meanwhile, depending on embodiments, additional capacitors or additional boost capacitors may be formed.

A plurality of wires 127, 128, 151, 152, 153, 155, 171, 172, and 741 are connected to one pixel PX.

The plurality of wires include a first initialization voltage line 127, a second initialization voltage line 128, a first scan line 151, a second scan line 152, an initialization control line 153, an emission control line 155, a data line 171, a driving voltage line 172, and a common voltage line 741.

The first scan line 151 is connected to a scan driver (not shown) to transfer a first scan signal GW to the second transistor T2 and the seventh transistor T7.

A voltage of polarity opposite to that applied to the first scan line 151 may be applied to the second scan line 152 at the same time as the signal of the first scan line 151.

For example, when a voltage of negative polarity is applied to the first scan line 151, a voltage of positive polarity may be applied to the second scan line 152.

The second scan line 152 transfers a second scan signal GC to the third transistor T3.

The initialization control line 153 transfers an initialization control signal GI to the fourth transistor T4.

The emission control line 155 transmits an emission control signal EM to the fifth transistor T5 and the sixth transistor T6.

The data line 171 is a wire that transmits a data voltage DATA generated by the data driver (not shown), and accordingly, the magnitude of the light emitting current delivered to the light emitting diode (LED) is changed so that the light emitting diode (LED) emits light according to the light emitting current.

The driving voltage line 172 applies the driving voltage ELVDD.

The first initialization voltage line 127 transfers the first initialization voltage VINT, and the second initialization voltage line 128 transfers the second initialization voltage VAINT.

The common voltage line 741 applies the common voltage ELVSS to the cathode of the light emitting diode LED.

In this embodiment, voltages applied to the driving voltage line 172, the first and second initialization voltage lines 127 and 128, and the common voltage line 741 may be constant voltages.

The driving transistor T1 (also referred to as a first transistor) is a p-type transistor, and has a silicon semiconductor (hereinafter referred to as a polycrystalline semiconductor or a first semiconductor) as a semiconductor layer.

This transistor adjusts the amount of light emitting current output to the anode of the light emitting diode LED according to the level of the voltage of the gate electrode of the driving transistor T1—that is, the voltage stored in the storage capacitor Cst.

Since the brightness of the light emitting diode (LED) is adjusted according to the magnitude of the light emitting current output to the anode electrode of the light emitting diode (LED), the light emitting luminance of the light emitting diode (LED) can be adjusted according to the data voltage (DATA) applied to the pixel.

To this end, the first electrode of the driving transistor T1 receive the driving voltage ELVDD, and is connected to the driving voltage line 172 via the fifth transistor T5.

In addition, the first electrode of the driving transistor T1 is also connected to the second electrode of the second transistor T2 to receive the data voltage DATA.

Meanwhile, the second electrode of the driving transistor T1 outputs a light emitting current through a light emitting diode (LED), and is connected to the anode of the light emitting diode (LED) via the sixth transistor (T6; also referred to as the output control transistor).

In addition, the second electrode of the driving transistor T1 is connected to the third transistor T3 to transfer the data voltage DATA applied to the first electrode to the third transistor T3.

Meanwhile, the gate electrode of the driving transistor T1 is connected to one electrode (hereinafter referred to as a second storage electrode) of the storage capacitor Cst.

The other electrode (hereinafter referred to as a first storage electrode) of the storage capacitor Cst receives the driving voltage ELVDD.

Accordingly, the voltage of the gate electrode of the driving transistor T1 is changed according to the voltage stored in the storage capacitor Cst, and the emission current output from the driving transistor T1 is changed.

The storage capacitor Cst serves to keep the voltage of the gate electrode of the driving transistor T1 constant for one frame.

Meanwhile, the gate electrode of the driving transistor T1 can be connected to the third transistor T3 so that the data voltage (DATA) applied to the first electrode of the driving transistor (T1) can be transmitted to the gate electrode of the driving transistor T1 through the third transistor T3.

Meanwhile, the gate electrode of the driving transistor T1 may also be connected to the fourth transistor T4 to be initialized by receiving the first initialization voltage VINT.

The second transistor T2 is a p-type transistor, and has a silicon semiconductor as a semiconductor layer.

The second transistor T2 is a transistor that transmits the data voltage DATA to the first electrode of the driving transistor T1.

The gate electrode of the second transistor T2 is connected to the first scan line 151 and one electrode of the boost capacitor C_{boost} (hereinafter referred to as a lower boost electrode).

The other electrode of the boost capacitor C_{boost} is connected to the gate electrode of the driving transistor T1 and the second storage electrode of the storage capacitor Cst.

Meanwhile, the first electrode of the second transistor T2 is connected to the data line 171, and the second electrode of the second transistor T2 is connected to the first electrode of the driving transistor T1.

When the second transistor T2 is turned on in response to the negative voltage of the first scan signal GW transmitted through the first scan line 151, the data voltage DATA transmitted through the data line 171. The data voltage DATA is finally transmitted to the gate electrode of the driving transistor T1, and stored in the storage capacitor Cst.

The third transistor T3 is an n-type transistor, and has an oxide semiconductor (hereinafter referred to as a second semiconductor) as a semiconductor layer.

The third transistor T3 electrically connects the second electrode of the driving transistor T1 and the gate electrode of the driving transistor T1.

As a result, the data voltage DATA is compensated by the threshold voltage of the driving transistor T1 and then stored in the second storage electrode of the storage capacitor Cst.

The gate electrode of the third transistor T3 is connected to the second scan line 152, and the first electrode of the third transistor T3 is connected to the second electrode of the driving transistor T1.

The second electrode of the third transistor T3 is connected to the second storage electrode of the storage capacitor Cst, the gate electrode of the driving transistor T1 and the other electrode (hereinafter referred to as upper boost electrode) of the boost capacitor C_{boost}.

The third transistor T3 is turned on in response to the voltage of the positive polarity among the second scan signal GC transmitted through the second scan line 152, and the gate electrode of the driving transistor T1 and the driving transistor T1 are turned on. The second electrode is connected, and the voltage applied to the gate electrode of the driving transistor T1 is transferred to the second storage electrode of the storage capacitor Cst and stored in the storage capacitor Cst.

The voltage stored in the storage capacitor Cst is the voltage of the gate electrode of the driving transistor T1 when the driving transistor T1 is turned off, so that the threshold voltage Vth of the driving transistor T1 is stored in a compensated state.

The fourth transistor T4 is an n-type transistor, and has an oxide semiconductor as a semiconductor layer.

The fourth transistor T4 serves to initialize the gate electrode of the driving transistor T1 and the second storage electrode of the storage capacitor Cst.

The gate electrode of the fourth transistor T4 is connected to the initialization control line 153, and the first electrode of the fourth transistor T4 is connected to the first initialization voltage line 127.

The second electrode of the fourth transistor T4 is the second electrode of the third transistor T3, the second storage electrode of the storage capacitor Cst, the gate electrode of the driving transistor T1, and the upper portion of the boost capacitor C_{boost}. It is connected to the boost electrode.

The fourth transistor T4 is turned on in response to a voltage of positive polarity among the initialization control signals GI transmitted through the initialization control line 153. The first initialization voltage VINT is applied to the gate electrode of the driving transistor T1, the second storage electrode of the storage capacitor Cst, and the upper boost electrode of the boost capacitor C_{boost} to initialize the gate electrode of the driving transistor T1, the second storage electrode of the storage capacitor Cst, and the upper boost electrode of the boost capacitor C_{boost}.

The fifth transistor T5 and the sixth transistor T6 are p-type transistors, and have a silicon semiconductor as a semiconductor layer.

The fifth transistor T5 serves to transfer the driving voltage ELVDD to the driving transistor T1.

The gate electrode of the fifth transistor T5 is connected to the emission control line 155, the first electrode of the fifth transistor T5 is connected to the driving voltage line 172, and the first electrode of the fifth transistor T5 is connected to the driving voltage line 172. The second electrode is connected to the first electrode of the driving transistor T1.

The sixth transistor T6 serves to transfer the light emitting current output from the driving transistor T1 to the light emitting diode LED.

The gate electrode of the sixth transistor T6 is connected to the emission control line 155, the first electrode of the sixth transistor T6 is connected to the second electrode of the driving transistor T1, and the sixth transistor (the second electrode of T6) is connected to the anode of the light emitting diode (LED).

The seventh transistor T7 is a p-type or n-type transistor, and may have a silicon semiconductor or an oxide semiconductor as a semiconductor layer. In the embodiment of FIG. 26, the seventh transistor T7 is a p-type transistor and includes a silicon semiconductor.

The seventh transistor T7 serves to initialize the anode of the light emitting diode (LED).

The gate electrode of the seventh transistor T7 is connected to the first scan line 151, the first electrode of the seventh transistor T7 is connected to the anode of the light emitting diode (LED) and the seventh transistor T7, the second electrode is connected to the second initialization voltage line 128.

Here, the gate electrode of the seventh transistor T7 is connected to the first scan line 151 of the previous pixel, and the same first scan line 151 as the gate electrode of the second transistor T2 belonging to the same pixel PX, but it may be connected to the same first scan line 151 as the gate electrode of the second transistor T2 of the previous pixel PX.

When the first scan line 151 is turned on by the voltage of the negative polarity, the seventh transistor T7 is turned on, and the second initialization voltage VAINT is applied to the anode of the light emitting diode LED, initializing it.

Meanwhile, the gate electrode of the seventh transistor T7 may be connected to a separate bypass control line through which the bypass signal GB is transmitted, and may be controlled by a separate wire from the first scan line 151.

Also, depending on embodiments, the second initialization voltage line 128 to which the second initialization voltage VAINT is applied may be the same as the first initialization voltage line 127 to which the first initialization voltage VINT is applied.

Although one pixel PX has been described as including seven transistors T1 to T7 and two capacitors (a storage capacitor Cst and a boost capacitor C_{boost}), the present inventive concept is not limited thereto. The capacitor C_{boost} may be omitted.

Also, depending on embodiments, an additional boost capacitor may be formed between the gate electrode of the third transistor T3 and the gate electrode of the driving transistor T1.

Also, although the third and fourth transistors are formed of n-type transistors, only one of them may be formed of n-type transistors, or other transistors (e.g., the seventh transistor) may be formed of n-type transistors.

As described above, a pixel of a display device includes two types of semiconductors positioned on different layers, and the two types of semiconductors are a polycrystalline semiconductor (also referred to as a first semiconductor) and an oxide semiconductor (also referred to as a second semiconductor), respectively.

Each of these is included in a transistor, and hereinafter, a transistor including a polycrystalline semiconductor is referred to as a polycrystalline transistor, and a transistor including an oxide semiconductor is referred to as an oxide transistor.

As such, one pixel may include a polycrystalline transistor and an oxide transistor, and the driving transistor T1 providing driving current to the light emitting diode (LED) is formed of a polycrystalline transistor.

All of the transistors other than the driving transistor T1 are also referred to as switching transistors, and the switching transistors may be classified into polycrystalline switching transistors and oxide switching transistors.

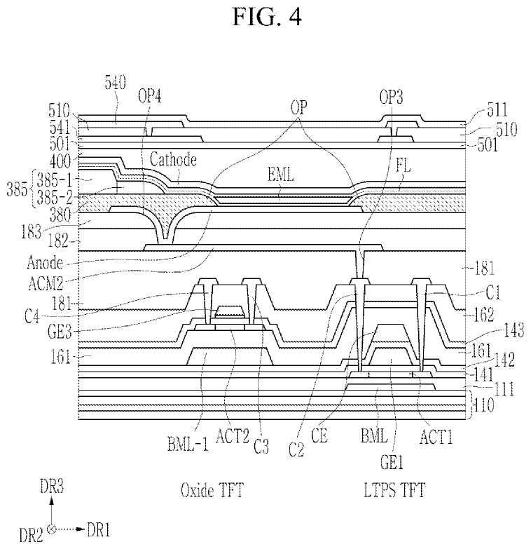

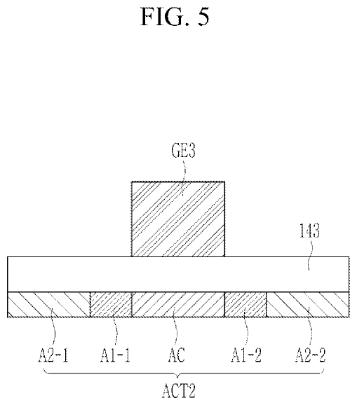

Hereinafter, a display device according to an embodiment will be described with reference to FIG. 4 and FIG. 5.

FIG. 4 is a cross-sectional view of a display device according to an embodiment, and FIG. 5 is a cross-sectional view of a second semiconductor layer.

The display device may include a lower panel layer and an upper panel layer, and the lower panel layer is a portion where light emitting diodes constituting pixels and pixel circuits are located, and may even include an encapsulation layer 400 covering them.

Here, the pixel circuit part includes the second organic layer 182 and the third organic layer 183. The light-emitting diode is disposed on top of the third organic layer 183.

A structure positioned above the encapsulation layer 400 may correspond to the upper panel layer, and may further include a color filter or a color conversion layer according to embodiments.

Also, depending on the embodiment, the third organic layer 183 may not be included.

First, a metal layer BML is positioned on the substrate 110.

The substrate 110 may include a rigid material, such as glass, that does not bend, or may include a flexible material that can bend, such as plastic or polyimide.

In the case of a flexible substrate, a double-layer structure of polyimide and a barrier layer formed of an inorganic insulating material thereon may have a double structure.

The metal layer BML may be formed at a position overlapping the channel of the driving transistor in a plan view and is also referred to as a lower shielding layer.

The metal layer BML may include a metal or a metal alloy such as copper (Cu), molybdenum (Mo), aluminum (Al), or titanium (Ti).

Here, the driving transistor may refer to a transistor that generates current transmitted to the light emitting diode.

A buffer layer 111 covering the substrate 110 and the metal layer BML is positioned.

The buffer layer 111 serves to block penetration of impurity elements into the first semiconductor layer ACT1 and may be an inorganic insulating layer including silicon oxide (SiOx), silicon nitride (SiNx), or silicon oxynitride (SiONx).

The first semiconductor layer ACT1 including a silicon semiconductor (e.g., a polycrystalline semiconductor (P—Si)) is positioned on the buffer layer 111.

The first semiconductor layer ACT1 includes a channel of a polycrystalline transistor including a driving transistor, and first and second regions positioned on both sides of the channel.

Here, the polycrystalline transistor may include a plurality of polycrystalline switching transistors as well as a driving transistor.

Also, the first and second regions disposed on both sides of the channel of the first semiconductor layer ACT1 may have an improved conductivity by plasma treatment or doping, and can perform the roles of the first and second electrodes of the transistor.

The first gate insulating layer 141 may be positioned on the first semiconductor layer ACT1.

The first gate insulating layer 141 may be an inorganic insulating layer including silicon oxide (SiOx), silicon nitride (SiNx), or silicon oxynitride (SiONx).

A first gate conductive layer including a gate electrode GE1 of a polycrystalline transistor may be positioned on the first gate insulating layer 141.

A scan line or an emission control line may be formed in the first gate conductive layer in addition to the gate electrode GE1 of the polycrystalline transistor.

Depending on embodiments, the first gate conductive layer formed of different materials may include a 1-1 gate conductive layer and a 1-2 gate conductive layer.

After forming the first gate conductive layer, an exposed region of the first semiconductor layer may be made conductive by performing a plasma treatment or a doping process.

In other words, the first semiconductor layer ACT1 covered by the first gate conductive layer does not have conductivity, and the portion of the first semiconductor layer ACT1 not covered by the first gate conductive layer may have conductivity similar to the conductive material.

The second gate insulating layer 142 may be positioned on the first gate conductive layer and the first gate insulating layer 141.

The second gate insulating layer 142 may be an inorganic insulating layer including silicon oxide (SiOx), silicon nitride (SiNx), or silicon oxynitride (SiONx).

A second gate conductive layer including one electrode CE of the storage capacitor Cst may be positioned on the second gate insulating layer 142.

One electrode CE of the storage capacitor Cst overlaps the gate electrode GE1 of the driving transistor to form the storage capacitor Cst.

According to embodiments, the second gate conductive layer may further include a lower shielding layer BML-1 of the oxide transistor.

The lower shielding layer BML-1 of the oxide transistor may be positioned below the channel of the oxide transistor to shield it from light or electromagnetic interference provided to the channel from the lower side.

According to embodiments, the second gate conductive layer may further include a scan line, a control line, or a voltage line.

The second gate conductive layer may include a metal or metal alloy such as copper (Cu), molybdenum (Mo), aluminum (Al), or titanium (Ti), and may be composed of a single layer or multiple layers.

A first interlayer insulating layer 161 may be positioned on the second gate conductive layer.

The first interlayer insulating layer 161 may include an inorganic insulating layer containing silicon oxide (SiOx), silicon nitride (SiNx), silicon oxynitride (SiONx), or the like, and depending on embodiments, an inorganic insulating material may be formed thickly.

A second semiconductor layer (an oxide semiconductor layer, ACT2) including an oxide semiconductor may be positioned on the first interlayer insulating layer 161.

Oxide semiconductors are based on a primary metal oxide such as indium oxide (In), tin oxide (Sn), or zinc oxide (Zn), a secondary metal oxide such as In—Zn oxide, Sn—Zn oxide, Al—Zn oxide, Zn—Mg oxide, Sn—Mg oxide, In—Mg oxide, or In—Ga oxide, In—Ga—Zn oxide, In—Al—Zn oxide, In—Sn—Zn oxide, Sn—Ga—Zn oxide, Al—Ga—Zn oxide, Sn—Al—Zn oxide, In—Hf—Zn oxide, In—La—Zn oxide, In—Ce—Zn oxide, In—Pr—Zn oxide, In—Nd—Zn oxide, In—Sm—Zn oxide, In—Eu—Zn oxide, In—Gd—Zn calcium oxide, In—Tb—Zn oxide, In—Dy—Zn oxide, In—Ho—Zn oxide, In—Er—Zn oxide, In—Tm—Zn oxide, In—Yb—Zn oxide, or In—Lu—Zn oxide, and at least one of a ternary metal oxide, such as an In—Sn—Ga—Zn oxide, an In—Hf—Ga—Zn calcium oxide, an In—Al—Ga—Zn oxide, an In—Sn—Al—Zn oxide, an In—Sn—Hf—Zn oxide, or an In—Hf—Al—Zn oxide.

For example, the second semiconductor layer ACT2 may include indium-gallium-zinc oxide (IGZO) among the In—Ga—Zn-based oxides.

The second semiconductor layer (ACT2) may include at least one of indium-gallium-zinc oxide (IGZO), indium-zinc-tin oxide (IZTO), indium-gallium-zinc-tin oxide (IGZTO), and indium-gallium oxide (IGO).

Referring to FIG. 5, the second semiconductor layer ACT2 may include a channel region AC overlapping the gate electrode GE3 of the oxide transistor to be described later, the first-1 region A1-1, the first-2 region A1-2, the second-1 region A2-1, and the second-2 region A2-2.

A 1-1 region A1-1 and a 1-2 region A1-2 may be positioned on both sides of the channel region AC, respectively. The 2-1 region A2-1 may be located next to the region A1-1, and the 2-2 region A2-2 may be located next to the 1-2 region A1-2. The 1-1 region A1-1 is disposed between the region A2-1 and the channel region AC, and the 1-2 region is disposed between the 2-2 region A2-2 and the channel region AC.

The length of the channel region AC may be 7 micrometers or less, for example, 3 micrometers or less.

The 1-1 region A1-1 and the 1-2 region A1-2 may be doped with first impurity ions.

The first impurity ion may be a p-type impurity ion. For example, the first impurity ion may be a boron (B) ion. A doping concentration of the first impurity ions may be 1×10¹² to 1×10¹³ ions/cm².

The second impurity ions may be doped in the 2-1 region A2-1 and the 2-2 region A2-2. The second impurity ion may include an impurity ion of a different type from the first impurity ion, and may be, for example, an n-type impurity ion. For example, the second impurity ion may include at least one of arsenic As ion and antimony Sb ion.

Also, according to another embodiment, the second impurity ion may include at least one of silicon Si ion, germanium Ge ion, and indium In ion. A doping concentration of the second impurity ion may be 1×10¹² to 1×10¹⁴ ions/cm².

The 2-1 region A2-1 and the 2-2 region A2-2 according to an embodiment may further include the first impurity ions. The first impurity ion may be a p-type impurity ion, and, for example, the first impurity ion may be a boron B ion.

The process of doping the second impurity ion having a relatively large atomic mass may cause damage to the oxide semiconductor, and, accordingly, the number of oxygen vacancies Vo included in the second semiconductor layer increases.

Oxygen vacancies react with hydrogen to form carriers, thus, the highly doped oxide semiconductor, for example, the 2-1 region A2-1 and the 2-2 region A2-2, may have higher conductivity than the lightly doped oxide semiconductor, for example, the 1-1 region A1-1 and the 1-2 region A1-2. The process of doping the first impurity ion having a relatively small atomic mass also causes damage to the oxide semiconductor, and accordingly, the number of oxygen vacancies Vo may increase as compared to a region which is not doped with the impurities. Oxygen vacancies react with hydrogen to form carriers, so that the low-concentration conductive regions, for example, the 1-1 region A1-1 and the 1-2 region A1-2, may have conductivity greater than the region which is not doped with impurities and less than the region which is doped with the second impurity ion. Since the first impurity ion has a smaller atomic mass than the second impurity ion, damage to the oxide semiconductor doped with the first impurity ion may be less than that of the oxide semiconductor doped with the second impurity ion. Accordingly, the number of oxygen vacancies generated in the region doped with the first impurity ion may be relatively small. Accordingly, the 1-1 region A1-1 and the 1-2 region A1-2 may have a lower carrier concentration than the 2-1 region A2-1 and the 2-2 region A2-2.

The carrier concentration may decrease toward the 2-1 region A2-1, the 1-1 region A1-1, the channel region AC, and the carrier concentration may decrease toward the 2-2 region A2-2, the 1-2 region A1-2 and the channel region AC. In the case of an oxide transistor including the second semiconductor layer ACT2 doped with different types of impurity ions, the threshold voltage value may be maintained substantially constant even if the length of the channel decreases. A short channel effect (SCE) may be improved, and hot carriers may be reduced. Accordingly, reliability of the transistor may be improved, and display quality of the display device may be improved.

A third gate Insulating layer 143″ may be positioned on the second semiconductor layer ACT2.

The third gate insulating layer 143 may be formed on the entire surface of the second semiconductor layer ACT2 and the first interlayer insulating layer 161, and some portions of the third gate insulating layer 143 may be removed to form contact holes.

The third gate insulating layer 143 may include an inorganic insulating layer including silicon oxide (SiOx), silicon nitride (SiNx), or silicon oxynitride (SiONx).

The third gate conductive layer including the gate electrode GE3 of an oxide transistor may be positioned on the third gate insulating layer 143.

The gate electrode GE3 of the oxide transistor may overlap the channel of the oxide transistor.

The third gate conductive layer may further include scan lines or control lines.

The third gate conductive layer may include a metal or metal alloy such as copper (Cu), molybdenum (Mo), aluminum (Al), or titanium (Ti), and may be composed of a single layer or multiple layers.

A second interlayer insulating layer 162 may be positioned on the third gate conductive layer.

The second interlayer insulating layer 162 may have a single-layer or multi-layer structure.

The second interlayer insulating layer 162 may include an inorganic insulating material such as silicon nitride (SiNx), silicon oxide (SiOx), and silicon oxynitride (SiOxNy), and may include an organic material according to embodiments.

A first data conductive layer, which includes connecting members (C1, C2, C3, C4) that can be connected to the first and second regions of each polycrystalline transistor and oxide transistor, can be located above the second interlayer insulation layer 162.

The first data conductive layer may include a metal or metal alloy such as aluminum (Al), copper (Cu), molybdenum (Mo), or titanium (Ti), and may be composed of a single layer or multiple layers.

A first organic layer 181 may be positioned on the first data conductive layer.

The first organic layer 181 may be an organic insulating layer including an organic material, and the organic material may include at least one material selected from the group consisting of polyimide, polyamide, acrylic resin, benzocyclobutene, and phenol resin.

A second data conductive layer including an anode connecting member ACM2 may be positioned on the first organic layer 181.

The second data conductive layer may include a data line or a driving voltage line.

The second data conductive layer may include a metal or metal alloy such as aluminum (Al), copper (Cu), molybdenum (Mo), or titanium (Ti), and may be composed of a single layer or multiple layers.

The anode connecting member ACM2 is connected to the first data conductive layer through the opening OP3 positioned in the first organic layer 181.

The second organic layer 182 and the third organic layer 183 are positioned above the second data conductive layer, and an anode connection opening OP4 is formed in the second organic layer (182) and the third organic layer 183.

The anode connection member ACM2 is electrically connected to the anode through the anode connection opening OP4.

The second organic layer 182 and the third organic layer 183 can be organic insulating layers, and may include one or more materials selected from the group consisting of polyimide, polyamide, acrylic resin, benzocyclobutene, and phenol resin.

Depending on embodiments, the third organic layer 183 may be omitted.

A pixel defining layer 380 covering at least a portion of the anode while having an opening OP exposing the anode may be positioned on the anode.

The pixel defining layer 380 may be a black pixel defining layer formed of a black organic material to prevent externally applied light from being reflected back to the outside, or may be formed of a transparent organic material according to embodiments.

A spacer 385 is positioned on the pixel defining layer 380.

The spacer 385 may be formed of a transparent organic insulating material.

According to an embodiment, the spacer 385 may be formed of a positive-type transparent organic material.

The spacer 385 may include two parts 385-1 and 385-2 having different heights, the high part 385-1 serving as a spacer, and the low part 385-2 may improve adhesion between the spacer and the pixel defining layer 380.

A functional layer (FL) and a cathode can be located on the anode, the spacer 385, and the pixel defining layer 380 to cover entire structure formed on the substrate 110.

The light emitting layer EML is positioned between the functional layers FL, and the light emitting layer EML may be positioned only within the opening OP of the pixel defining layer 380.

Hereinafter, the functional layer FL and the light emitting layer EML may be collectively referred to as an intermediate layer.

The functional layer FL may include at least one of an electron injection layer, an electron transport layer, a hole transport layer, and an auxiliary layer such as a hole injection layer, and the hole injection layer and the hole transport layer are disposed under the light emitting layer EML, and an electron transport layer and an electron injection layer may be located on the light emitting layer EML.

The encapsulation layer 400 is positioned on the cathode.

The encapsulation layer 400 includes at least one inorganic layer and at least one organic layer, and may have a triple-layer structure including a first inorganic encapsulation layer, an organic encapsulation layer, and a second inorganic encapsulation layer.

The encapsulation layer 400 may protect the light emitting layer EML from moisture or oxygen that may be introduced from the outside.

Depending on the embodiment, the encapsulation layer 400 may include a structure in which an inorganic layer and an organic layer are sequentially stacked.

On the encapsulation layer 400, sensing insulating layers 501, 510, and 511 and a plurality of sensing electrodes 540 and 541 are positioned for touch sensing.

A touch may be sensed in a capacitive type using the two sensing electrodes 540 and 541.

Specifically, a first sensing insulating layer 501 is formed on the encapsulation layer 400, and a plurality of sensing electrodes 540 and 541 are formed thereon.

The plurality of sensing electrodes 540 and 541 may be insulated with the second sensing insulating layer 510 interposed therebetween, and some may be electrically connected through openings located in the sensing insulating layer 510.

Here, the sensing electrodes 540 and 541 include metal or metal alloys such as aluminum (Al), copper (Cu), silver (Ag), gold (Au), molybdenum (Mo), titanium (Ti), and tantalum (Ta), and they may include a single layer or multiple layers.

A third sensing insulating layer 511 is formed on the sensing electrode 540.

In FIG. 4, there is no additional layer disposed on top of the third sensing insulating layer 511, but a layer including a polarizing plate may be attached on the third sensing insulating layer 511 to reduce the reflection of external light, or a color filter or color conversion layer may be further formed on the third sensing insulating layer 511 to improve color quality.

A light blocking member may be positioned between the color filters or the color conversion layer.

In addition, depending on the embodiment, a layer having a material capable of absorbing some wavelengths of external light (hereinafter referred to as a reflection adjusting material) may be further included.

In addition, depending on the embodiment, the front surface of the light emitting display device may be flattened by covering it with an additional organic layer (also referred to as a planarization layer).

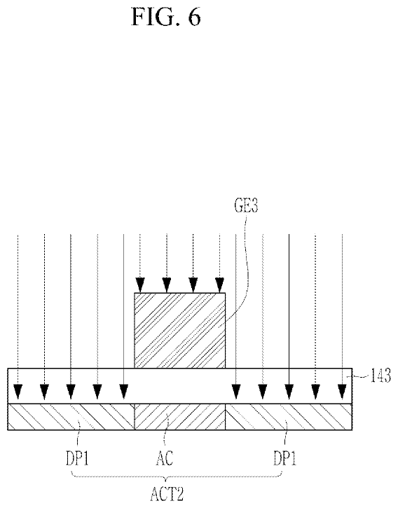

Hereinafter, a manufacturing process of the second semiconductor layer according to an embodiment will be described with reference to FIG. 6 to FIG. 9.

FIG. 6 to FIG. 9 are cross-sectional views of a manufacturing process of a second semiconductor layer according to an embodiment.

Descriptions of components identical to those described above will be omitted.

First, referring to FIG. 6, a second semiconductor layer ACT2 including an oxide semiconductor, the third gate insulating layer 143 and the gate electrode GE3 of an oxide transistor are formed. Thereafter, a first doping process using first impurity ions is performed.

A doping process may be performed using the gate electrode GE3 as a self-aligned mask. By the first doping process, the second semiconductor layer ACT2 located on both sides of the channel region AC not to overlap the gate electrode GE3, for example, a region DP1, doped with the first impurity ions is formed.

The channel region AC is not doped with impurity ions because the gate electrode GE3 is used as a mask, and both sides of the channel region AC may be doped with first impurity ions. The first impurity ion may be a p-type impurity ion. For example, the first impurity ion may be a B ion. The doping concentration of the first impurity ions may be 1×10¹² to 1×10¹³ ions/cm².

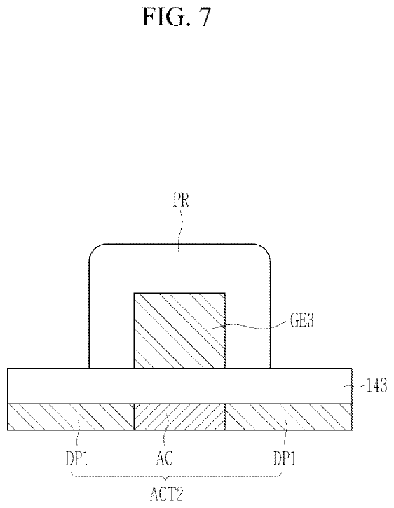

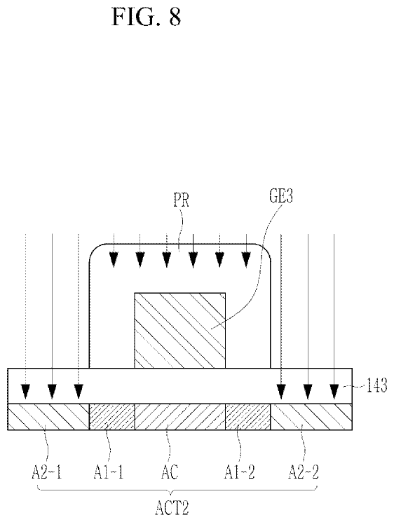

As shown in FIG. 7, a photosensitive resin composition pattern PR is formed on the gate electrode GE3 of the oxide transistor. Then, as shown in FIG. 8, a second doping process using the second impurity ions is performed. The second impurity ion may include an impurity ion different from the first impurity ion, and may be, for example, an n-type impurity ion. For example, the second impurity ion may include at least one of As and Sb. Also, the second impurity ion according to another embodiment may include at least one of Si, Ge, and In. A doping concentration of the second impurity ion may be greater than or equal to the doping concentration of the first impurity ions, for example, 1×10¹² to 1×10¹⁴ ions/cm².

According to this doping process, second impurity ions may be doped into a portion of the second semiconductor layer ACT2 not covered by the photosensitive resin composition pattern PR. The second semiconductor layer ACT2 includes the channel region AC, the 1-1 region A1-1, the 1-2 region A1-2, the 2-1 region A2-1, and the 2-2 region A2-2.

The 1-1 region A1-1 and the 1-2 region A1-2 may be doped with the first impurity ions, and the 2-1 region A2-1 and the 2-2 region A2-2 may be doped with the first impurity ions and the second impurity ions.

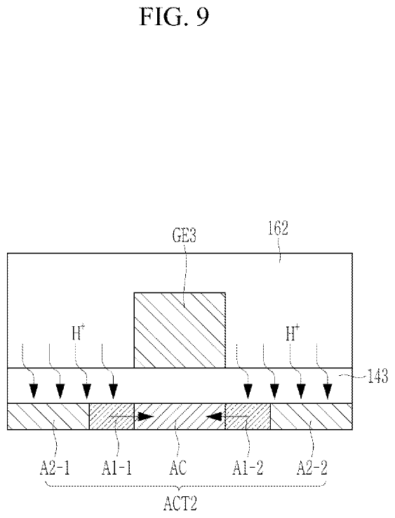

Then, as shown in FIG. 9, the photosensitive resin composition pattern PR is removed and the second interlayer insulating layer 162 is formed on the gate electrode GE3. Hydrogen included in the second interlayer insulating layer 162 may diffuse into the second semiconductor layer ACT2 to form additional carriers.

A process of doping the second impurity ion having a relatively large atomic mass may cause relatively large damage to the oxide semiconductor, and accordingly, the number of oxygen vacancies Vo included in the second semiconductor layer may increase.

Oxygen vacancies react with hydrogen to form carriers, thus, the highly doped oxide semiconductor, for example, the 2-1 region A2-1 and the 2-2 region A2-2, may have higher conductivity than the lightly doped oxide semiconductor, for example, the 1-1 region A1-1 and the 1-2 region A1-2. The process of doping the first impurity ion having a relatively small atomic mass may cause relatively small damage to the oxide semiconductor. In this case, oxygen vacancies (Vo) are generated, and the generated oxygen vacancies react with hydrogen to form carriers, thereby forming a low-concentration conductive region that constitutes the 1-1 region (A1-1) and the 1-2 region (A1-2). Since the first impurity ion has a smaller atomic mass than the second impurity ion, damage to the oxide semiconductor may be relatively small in the 1-1 region A1-1 and the 1-2 region A1-2. Accordingly, the number of oxygen vacancies generated by doping the first impurity ions may be smaller than the number of oxygen vacancies generated by doping the second impurity ions. Accordingly, the 1-1 region A1-1 and the 1-2 region A1-2 having a lower carrier concentration than the second impurity ion are formed by the first impurity ions.

In the case of an oxide transistor including the second semiconductor layer ACT2 doped with different types of impurity ions, the threshold voltage value may be maintained substantially constant even if the length of the channel decreases. A short channel effect (SCE) may be improved and hot carriers may be reduced. Accordingly, reliability of the transistor may be improved, and display quality of the display device may be improved.

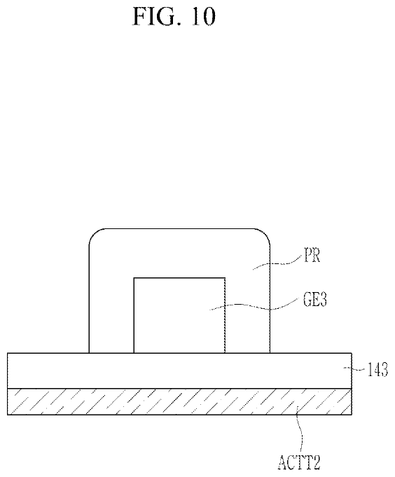

Hereinafter, a manufacturing process of the second semiconductor layer according to an embodiment will be described with reference to FIG. 10 to FIG. 13.

FIG. 10 to FIG. 13 are cross-sectional views of a manufacturing process of a second semiconductor layer according to another embodiment.

Referring to FIG. 10, the photosensitive resin composition pattern PR is formed on the gate electrode GE3 of the oxide transistor.

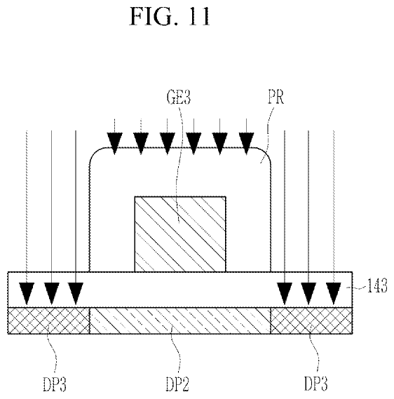

Then, as shown in FIG. 11, a doping process using the second impurity ions is performed.

According to the doping process, the second semiconductor layer ACT2 overlapping the gate electrode GE3 and/or the photosensitive resin composition pattern PR, for example, a region DP2, is not doped with the second impurity ion and regions located on both sides of the region DP2 are doped with the second impurity ions.

The second impurity ion may include an impurity ion of a different type from the first impurity ion, and may be, for example, an n-type impurity ion. For example, the second impurity ion may include at least one of As and Sb. Also, the second impurity ion according to another embodiment may include at least one of Si, Ge, and In. A doping amount of the second impurity ion may be 1×10¹² to 1×10¹⁴ ions/cm².

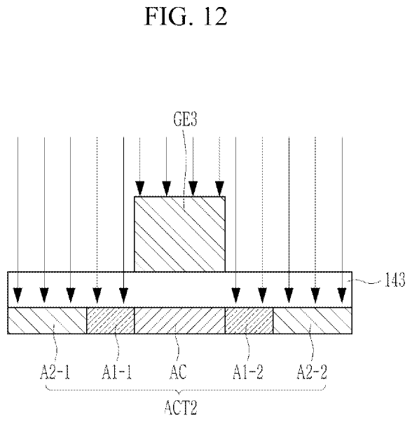

After that, as shown in FIG. 12, the photosensitive resin composition pattern PR is removed, and a doping process using first impurity ions is performed. Through the doping process, the second semiconductor layer ACT2 has a channel region AC, a 1-1 region A1-1, a 1-2 region A1-2, a 2-1 region A2-1, and a 2-2 region A2-2. The first impurity ion is doped in a 1-1 region A1-1, a 1-2 region A1-2, a 2-1 region A2-1, and a 2-2 region A2-2, and the second impurity ion is doped in a 2-1 region A2-1 and a 2-2 region A2-2. The first impurity ion may be a p-type impurity ion. For example, the first impurity ion may be a B ion. A doping amount of the first impurity ions may be 1×10¹² to 1×10¹³ ions/cm².

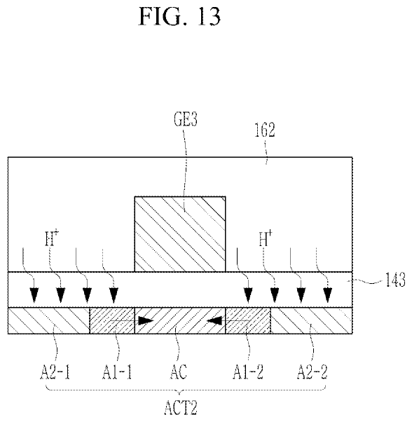

Afterwards, as shown in FIG. 13, the second interlayer insulating layer 162 is formed on the gate electrode GE3. Hydrogen included in the second interlayer insulating layer 162 may diffuse into the second semiconductor layer ACT2 to form additional carriers.

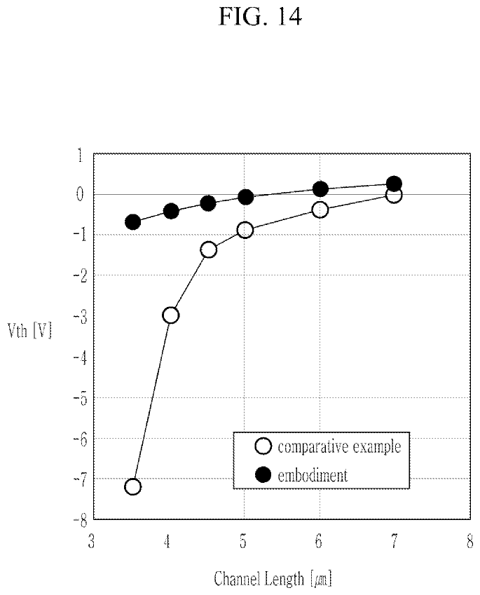

Hereinafter, with reference to FIG. 14, comparative examples and embodiments of the inventive concept will be described. FIG. 14 is a graph showing threshold voltage values of transistors including an oxide semiconductor according to the embodiments of the inventive concept and comparative examples.

Referring to FIG. 14, the comparative example is a transistor including an oxide semiconductor layer which includes only an n+ region and a channel region, and the embodiments of the inventive concept is a transistor including an oxide semiconductor layer which includes a 1-1 region, a 1-2 region, a 2-1 region, and a 2-1 region.

In the case of the comparative example, it was confirmed that the threshold voltage value rapidly decreased as the length of the channel was shortened.

On the other hand, in the case of the embodiment of the inventive concept, it was confirmed that the threshold voltage value was kept constant to some extent even though the length of the channel was shortened.

In the case of including the oxide semiconductor layer according to the embodiment of the inventive concept, since the threshold voltage of the oxide transistor is stable, a display device with improved reliability may be provided.

In addition, since the channel length of the oxide transistor can be shortened without deteriorating the characteristic of the oxide transistor, it is possible to provide a display device with improved resolution.

Although the embodiments of the present inventive concept have been described in detail above, the scope of the present inventive concept is not limited thereto, and various modifications and improvements of those skilled in the art using the basic concepts of the present inventive concept defined in the following claims are also included in the scope of the present inventive concept.

What is claimed is:

1. A display device, comprising:
a substrate; and
a transistor, the transistor including an oxide semiconductor layer as an active layer and a gate electrode disposed on the oxide semiconductor layer to overlap the oxide semiconductor layer,
wherein the oxide semiconductor layer includes:
a channel region, and
a source region disposed on a first side of the channel region and a drain region disposed on s second side of the channel region,
wherein the source region includes a first source region disposed adjacent to the channel region and a second source region disposed adjacent to the first source region, and the drain region include a first drain region disposed adjacent to the channel region and a second drain region disposed adjacent to the first drain region, and wherein each of the first source region and the first drain region includes a first impurity ion, and each of the second source region and the second drain region includes a second impurity ion which are different from the first impurity.

2. The display device of claim 1, wherein:
the second source region and the second drain region further include the first impurity ion.

3. The display device of claim 1, wherein:
atomic mass of the second impurity ion is greater than the atomic mass of the first impurity ion.

4. The display device of claim 3, wherein:
the first impurity ion is a p-type impurity and the second impurity ion is an n-type impurity.

5. The display device of claim 4, wherein:
the first impurity ion includes B and the second impurity ion includes at least one of As, Sb, Si, Ge, and an In.

6. The display device of claim 1, wherein:
doping concentration of the first source region and the first drain region is lower than that of the second source region and the second drain region.

7. The display device of claim 6, wherein:
a doping concentration of the first impurity ions is 1×10¹² ions/cm² to 1×10¹³ ions/cm².

8. The display device of claim 6, wherein:
a doping concentration of the second impurity ions is 1×10¹² ions/cm² to 1×10¹⁴ ions/cm².

9. The display device of claim 1, wherein:
each of the first source region and the second source region includes B.

10. The display device of claim 1, wherein:
each of the second source region and the second drain region includes B and at least one of As, Sb, Si, Ge, and In.

11. A manufacturing method of a display device, comprising:
forming an oxide semiconductor layer on a substrate;
forming a gate insulating layer on the oxide semiconductor layer;
forming a gate electrode on the gate insulating layer;
doping a first impurity ion in the oxide semiconductor layer, and
doping a second impurity ion in the oxide semiconductor layer,
wherein the first impurity ion includes a p-type impurity ion, and the second impurity ion includes an impurity ion of a different type from the first impurity ion.

12. The manufacturing method of the display device of claim 11, wherein:
the second impurity ion includes an n-type impurity ion.

13. The manufacturing method of the display device of claim 12, further comprising:
forming a mask which covers side surface of the gate electrode before the doping of the second impurity ion in the oxide semiconductor layer.

14. The manufacturing method of the display device of claim 13, wherein:
the mask is a photosensitive pattern.

15. The manufacturing method of the display device of claim 14, further comprising:
removing the mask after the doping of the second impurity ion in the oxide semiconductor layer.

16. The manufacturing method of the display device of claim 13, wherein:
the first impurity ion is B and the second impurity ion is at least one of As, Sb, Si, Ge, and an In.

17. The manufacturing method of the display device of claim 12, further comprising:
forming a mask which covers side surface of the gate electrode before the doping of the first impurity ion in the oxide semiconductor layer and the doping of the second impurity ion in the oxide semiconductor.

18. The manufacturing method of the display device of claim 17, further comprising:
removing the mask before the doping of the first impurity ion in the oxide semiconductor layer.

19. The manufacturing method of the display device of claim 11, wherein:
a doping concentration of the first impurity ion is 1×10¹² to 1×10¹³ ions/cm².

20. The manufacturing method of the display device of claim 11, wherein:
a doping concentration of the second impurity ion is 1×10¹² to 1×10¹⁴ ions/cm².
